(19) United States
(12) Patent Application Publication
(10) Pub. No.: US 2025/0105587 A1
(43) Pub. Date: Mar. 27, 2025

(54) OPTICAL MODULE

(71) Applicant: NEC Corporation, Tokyo (JP)

(72) Inventor: Isao TOMITA, Tokyo (JP)

(73) Assignee: NEC Corporation, Tokyo (JP)

(21) Appl. No.: 18/888,288

(22) Filed: Sep. 18, 2024

(30) Foreign Application Priority Data
Sep. 22, 2023 (JP) 2023-156660

(51) Int. Cl. H01S 5/024

(52) U.S. Cl. CPC H01S 5/02476; H01S 5/02438

(57) ABSTRACT

An optical module according to the present disclosure includes: a first heat spreader having a first surface; a second heat spreader having a second surface having a smaller area than that of the first surface and being attached to the first heat spreader after the second surface and the first surface are in contact with each other; an optical processing circuit attached to the first heat spreader at a portion of the first surface that is not in contact with the second surface and configured to process and output light; and an optical amplifier attached to the second heat spreader at an opposite surface of the second surface and configured to amplify and output the light being output from the optical processing circuit.

### INCORPORATION BY REFERENCE

This application is based upon and claims the benefit of priority from Japanese patent application No. 2023-156660, filed on Sep. 22, 2023, the disclosure of which is incorporated herein in its entirety by reference.

### TECHNICAL FIELD

The present disclosure relates to an optical module.

### BACKGROUND ART

One example of the optical module includes a laser unit configured by combining a silicon photonics (SiP) element, a semiconductor optical amplifier (SOA), and a booster optical amplifier (BOA).

In the above-described laser unit, the SiP element, the SOA, and the BOA become heating elements, and temperature control is required.

Herein, in order to cool the heating element at lower power consumption in a thermo electric cooler (TEC), it is effective to increase heat absorption efficiency in the TEC.

In addition, in order to increase the heat absorption efficiency in the TEC, a structure in which heat of the heating element is uniformly diffused into the TEC by a heat spreader is effective. A heat dissipation mechanism using the heat spreader is disclosed in, for example, Japanese Unexamined Patent Application Publication No.2019-145536.

Therefore, in the above-described laser unit, the SiP element, the SOA, and the BOA are attached to heat spreaders after the SiP element, the SOA, and the BOA are in contact with the heat spreaders, and then heat of the SiP element, the SOA, and the BOA is diffused by the heat spreaders.

Incidentally, in the above-described laser unit, in order to form the SiP element at a low cost, it is effective to reduce a degree of freedom of thickness of the heat spreader in contact with the SiP element, for example, to make the thickness constant.

In consideration of a structure of the above-described laser unit, a structure in which the heat spreaders in contact with the SiP element, the SOA, and the BOA are to be the same heat spreader is effective. However, in a case of this structure, the thickness of the heat spreader in contact with the SOA and the BOA becomes the same as the thickness of the heat spreader in contact with the SiP element, although an amount of heat generation is larger in the SOA and the BOA than in the SiP element. Therefore, in the above-described structure, there is a problem that heat of the SOA and the BOA cannot be sufficiently diffused.

Hereinafter, the above-described problem is described with reference to FIG. 1, taking a BOA among SOA and BOA as an example. The upper drawing of FIG. 1 illustrates a graph indicating a relationship between a lower surface heat radiation width and a total temperature rise with respect to the thickness of the heat spreader in contact with the BOA. In the upper drawing of FIG. 1, the values on the vertical axis are examples and are expressed as ratios to a reference value when the reference value is set to 1. In addition, the lower drawing of FIG. 1 illustrates a state of heat diffusion of the BOA when the thickness of the heat spreader in contact with the BOA is about 200 [p82 m] and about 600 [μm], respectively.

As illustrated in FIG. 1, when the thickness of the heat spreader in contact with the BOA is about 200 [μm], the lower surface heat radiation width cannot be sufficiently secured. Therefore, the heat spreader in contact with the BOA has insufficient heat diffusion, and thus the heat absorption efficiency in the TEC is deteriorated. However, a temperature rise of the heat spreader in contact with the BOA is suppressed.

Meanwhile, when the thickness of the heat spreader in contact with the BOA is about 600 [μm], the lower surface heat radiation width can be sufficiently secured. Therefore, the heat spreader in contact with the BOA has sufficient heat diffusion, and the heat absorption efficiency in the TEC is high. In addition, the temperature rise of the heat spreader in contact with the BOA is also suppressed.

Therefore, in a case where the thickness of the heat spreader in contact with the SiP element is constant and is about 200 [μm], when the thickness of the heat spreader in contact with the BOA is the same as the thickness of the heat spreader in contact with the SiP element, heat of the BOA cannot be sufficiently diffused.

Therefore, the thickness of the heat spreader in contact with the BOA needs to be larger than the thickness of the heat spreader in contact with the SiP element. In addition, the SOA also has a higher amount of heat generation than the SiP element, and thus indicates the same tendency as that of the BOA. Therefore, the thickness of the heat spreader in contact with the SOA also needs to be larger than the thickness of the heat spreader in contact with the SiP element.

### SUMMARY

Therefore, an example object of the present disclosure is to provide, in view of the above-described problem, an optical module capable of providing an appropriate thickness of a heat spreader in contact with each of a plurality of elements serving as a heating element.

In a first example aspect, an optical module includes: a first heat spreader having a first surface; a second heat spreader having a second surface with a smaller area than the first surface, and being attached to the first heat spreader after the second surface is in contact with the first surface; an optical processing circuit attached to the first heat spreader at a portion of the first surface that is not in contact with the second surface, and configured to process and output light; and an optical amplifier attached to the second heat spreader and configured to amplify and output the light.

### BRIEF DESCRIPTION OF DRAWINGS

The above and other aspects, features, and advantages of the present disclosure will become more apparent from the following description of certain example embodiments when taken in conjunction with the accompanying drawings, in which:

FIG. 1 is a diagram describing an appropriate thickness of a heat spreader in contact with a BOA;

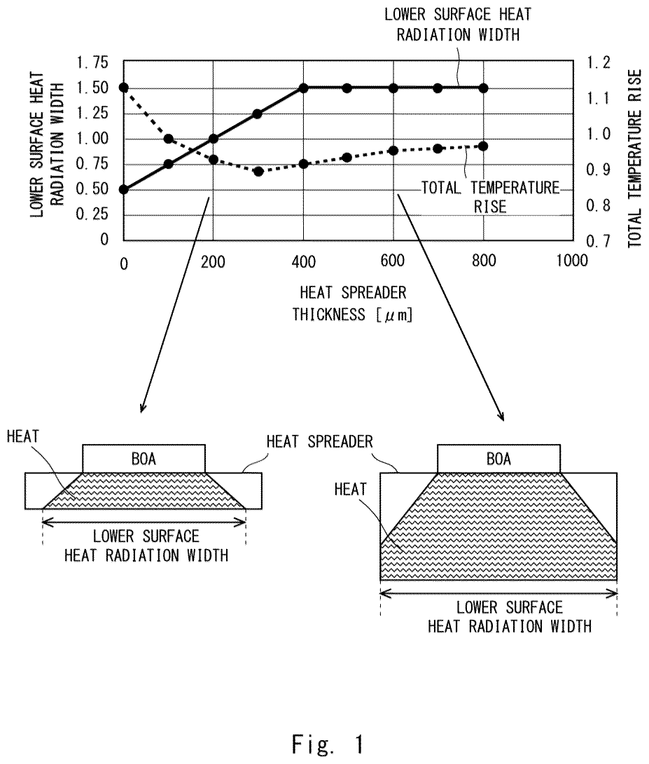

FIG. 2 is a perspective view illustrating a configuration example of an optical module according to the present disclosure;

FIG. 3 is a front view illustrating a configuration example of the optical module according to the present disclosure;

FIG. 4 is a front view illustrating a configuration example of the optical module according to the present disclosure;

FIG. 5 is a perspective view illustrating a configuration example of the optical module according to the present disclosure;

FIG. 6 is a front view illustrating a configuration example of the optical module according to the present disclosure;

FIG. 7 is a front view illustrating a configuration example of the optical module according to the present disclosure;

FIG. 8 is a front view illustrating a configuration example of the optical module according to the present disclosure; and

FIG. 9 is a plan view illustrating a configuration example of the optical module according to the present disclosure.

### EXAMPLE EMBODIMENT

Hereinafter, example embodiments of the present disclosure will be described with reference to the drawings. Note that the following description and the drawings are omitted and simplified as appropriate for clarity of description. In the following drawings, the same elements are denoted by the same reference numerals, and redundant descriptions are omitted as necessary. Further, in the following description, a laser unit is described as an example of the optical module, but the example of the optical module is not limited to the laser unit.

### First Example Embodiment

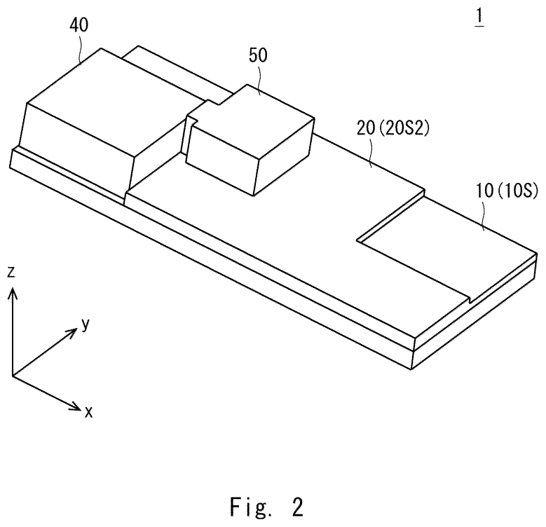

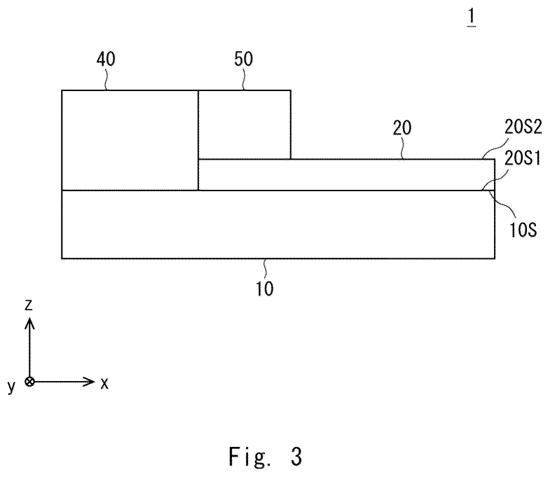

A configuration example of an optical module 1 will be described with reference to FIGS. 2 and 3. FIG. 2 is a perspective view illustrating a configuration example of the optical module 1, and FIG. 3 is a front view illustrating a configuration example of the optical module 1.

As illustrated in FIGS. 2 and 3, the optical module 1 is a laser unit including a first heat spreader 10, a second heat spreader 20, a SiP element 40, and a BOA 50.

The first heat spreader 10 has a first surface 10S. Specifically, in the examples of FIGS. 2 and 3, the first heat spreader 10 (the first surface 10S) has a rectangular shape in plan view. However, the present disclosure is not limited thereto, and the first heat spreader 10 (the first surface 10S) may have another shape such as a square shape in plan view.

The second heat spreader 20 has a second surface 20S1 that is smaller in area than the first surface 10S. Specifically, in the examples of FIGS. 2 and 3, the second heat spreader 20 (the second surface 20S1 and an opposite surface 20S2) has a Z shape in which notches are formed at two diagonal corners of a rectangle in plan view. However, the present disclosure is not limited thereto, and the second heat spreader 20 (the second surface 20S1 and the opposite surface 20S2) may have another shape such as a shape in which notches are formed at two diagonal corners of a square in plan view.

The second heat spreader 20 is attached to the first heat spreader 10 after the second surface 20S1 and the first surface 10S are in contact with each other.

The SiP element 40 is attached to the first heat spreader 10 at a portion of the first surface 10S that is not in contact with the second surface 20S1. Specifically, in the example of FIGS. 2 and 3, the SiP element 40 is attached to the first heat spreader 10 at a portion of the first surface 10S that is not in contact with the second surface 20S1, and corresponds to one of the two notches described above.

The SiP element 40 is an optical processing circuit that processes and outputs light.

The BOA 50 is attached to the second heat spreader 20 at the opposite surface 20S2 of the second surface 20S1 (i.e., the back surface; hereinafter, the same is applied).

The BOA 50 is a chip on carrier (CoC)-type optical amplifier that amplifies and outputs the light output from the SiP element 40.

The first heat spreader 10 and the second heat spreader 20 may be formed by metal plates different from each other. Alternatively, the first heat spreader 10 and the second heat spreader 20 may be formed by a single metal plate.

As described above, according to the first example embodiment, the first heat spreader 10 has the first surface 10S. The second heat spreader 20 has the second surface 20S1 having a smaller area than the first surface 10S, and is attached to the first heat spreader 10 after the second surface 20S1 and the first surface 10S are in contact with each other. The SiP element 40 is attached to the first heat spreader 10 at a portion of the first surface 10S that is not in contact with the second surface 20S1. Further, the BOA 50 is attached to the second heat spreader 20 on the opposite surface 20S2 of the second surface 20S1.

Therefore, the thickness of the heat spreader in contact with the SiP element 40 is the thickness of the first heat spreader 10. On the other hand, the thickness of the heat spreader in contact with the BOA 50 having a larger amount of heat generation than that of the SiP element 40 is the thickness obtained by adding the thickness of the first heat spreader 10 and the thickness of the second heat spreader 20, and therefore is larger than the thickness of the heat spreader in contact with the SiP element 40. Accordingly, the heat spreaders in contact with each of the SiP element 40 and the BOA 50 serving as heating elements can have an appropriate thickness.

### Second Example Embodiment

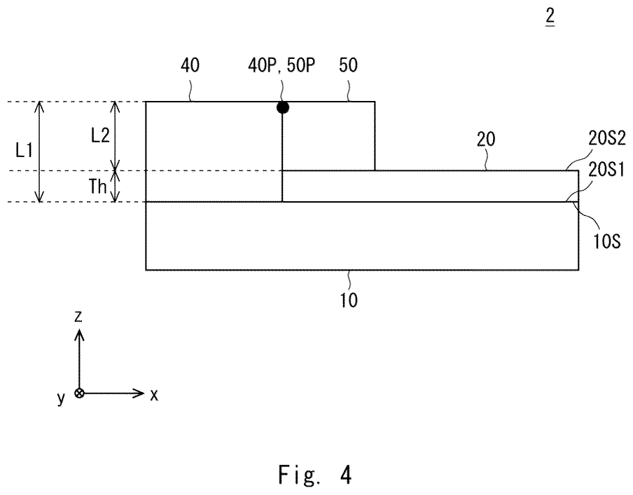

A configuration example of an optical module 2 will be described with reference to FIG. 4. FIG. 4 is a front view illustrating a configuration example of the optical module 2.

As illustrated in FIG. 4, in the optical module 2, the SiP element 40 includes an optical output port 40P that outputs light processed by the SiP element 40. The BOA 50 includes an optical input port 50P to which the light output from the optical output port 40P is input.

Here, it is assumed that a first length (length in the z-axis direction) from a bottom surface of the SiP element 40 to the light output port 40P is L1, and a second length (length in the z-axis direction) from a bottom surface of the BOA 50 to the light input port 50P is L2. In this case, the thickness Th of the second heat spreader 20 is a difference between the first length L1 described above and the second length L2 described above. As described above, by adjusting the thickness Th of the second heat spreader 20, the positions of the optical output port 40P and the optical input port 50P in the z-axis direction can be matched.

The other configurations of the optical module 2 are the same as those of the optical module 1 described above.

As described above, according to the second example embodiment, the thickness Th of the second heat spreader 20 is a difference between the first length L1 from the bottom surface of the SiP element 40 to the light output port 40P and the second length L2 from the bottom surface of the BOA 50 to the light input port 50P. Accordingly, the positions of the optical output port 40P and the optical input port 50P can be matched.

Other effects are the same as those of the first example embodiment described above.

### Third Example Embodiment

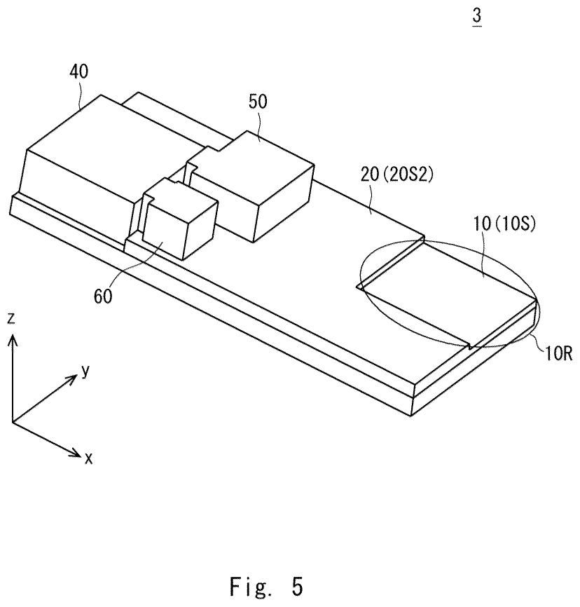

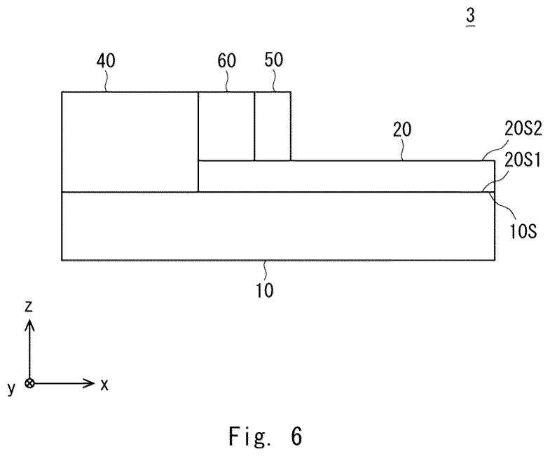

A configuration example of an optical module 3 will be described with reference to FIGS. 5 and 6. FIG. 5 is a perspective view illustrating a configuration example of the optical module 3, and FIG. 6 is a front view illustrating a configuration example of the optical module 3.

As illustrated in FIGS. 5 and 6, the optical module 3 has a configuration in which a SOA 60 is added to the above-described optical module 1.

The SOA 60 is attached to the second heat spreader 20 at the opposite surface 20S2 of the second surface 20S1.

The SOA 60 is a CoC-type light source that outputs light to the SiP element 40.

As described above, according to the third example embodiment, the SOA 60 is added to the optical module 1. Further, the SOA 60 is attached to the second heat spreader 20 on the opposite surface 20S2 of the second surface 20S1.

Therefore, the thickness of the heat spreader in contact with the SOA 60 having a larger amount of heat generation than that of the SiP element 40 is the thickness obtained by adding the thickness of the first heat spreader 10 and the thickness of the second heat spreader 20, and thus is larger than the thickness of the heat spreader in contact with the SiP element 40. Accordingly, the heat spreaders in contact with each of the SiP element 40, the BOA 50, and the SOA 60 serving as heating elements can be made to have an appropriate thickness.

### Fourth Example Embodiment

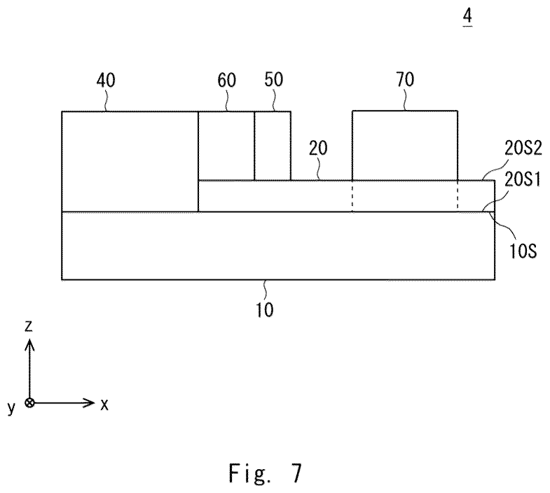

A configuration example of an optical module 4 will be described with reference to FIG. 7. FIG. 7 is a front view illustrating a configuration example of the optical module 4.

As illustrated in FIG. 7, the optical module 4 has a configuration in which an isolator 70 is added to the above-described optical module 3.

The isolator 70 is attached to the first heat spreader 10 at a portion of the first surface 10S that is not in contact with the second surface 20S1. Specifically, in the example of FIG. 7, the second heat spreader 20 (the second surface 20S1 and the opposite surface 20S2) has a Z shape in which notches are formed at two diagonal corners of a rectangle in plan view. The isolator 70 is attached to the first heat spreader 10 at a portion of the first surface 10S that is not in contact with the second surface 20S1, and corresponds to one of the two notches described above (specifically, a portion of a region 10R of FIG. 5). Note that the SiP element 40 is attached to a portion of the first surface 10S that is not in contact with the second surface 20S1 and corresponds to the other of the two notches described above.

The isolator 70 transmits the light output from the BOA 50 only in the output direction (x-axis plus direction), and blocks the light in the opposite direction (x-axis minus direction) of the output direction. As a result, it is possible to prevent the reflected light or the like of the light output from the BOA 50 from reaching the BOA 50.

As described above, according to the fourth example embodiment, the isolator 70 is added to the optical module 3 described above. The isolator 70 is attached to the first heat spreader 10 at a portion of the first surface 10S that is not in contact with the second surface 20S1. As a result, it is possible to prevent the reflected light or the like of the light output from the BOA 50 from reaching the BOA 50.

Other effects are the same as those of the above-described third example embodiment.

### Fifth Example Embodiment

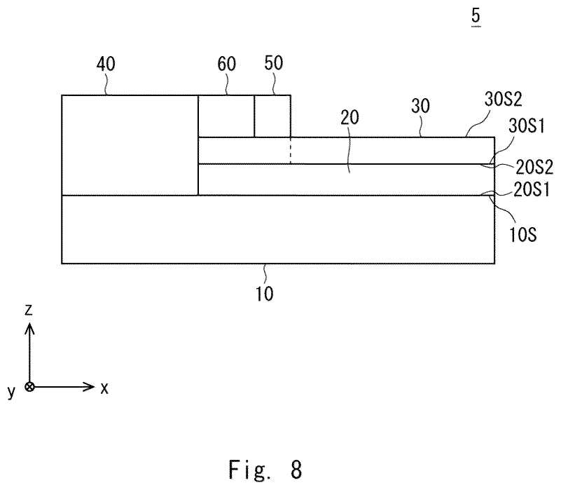

A configuration example of an optical module 5 will be described with reference to FIG. 8. FIG. 8 is a front view illustrating a configuration example of the optical module 5.

As illustrated in FIG. 8, the optical module 5 has a configuration in which a third heat spreader 30 and the SOA 60 are added to the optical module 1 described above.

The third heat spreader 30 has a third surface 30S1 having a smaller area than the opposite surface 20S2 of the second surface 20S1, and is attached to the second heat spreader 20 after the third surface 30S1 and the opposite surface 20S2 of the second surface 20S1 are in contact with each other.

Therefore, in the fifth example embodiment, the BOA 50 is attached to the second heat spreader 20 at a portion of the opposite surface 20S2 of the second surface 20S1 that is not in contact with the third surface 30S1.

The SOA 60 is attached to the third heat spreader 30 at an opposite surface 30S2 of the third surface 30S1. Therefore, when the thickness of the BOA 50 is larger than the thickness of the SOA 60, a difference between the thicknesses of the two can be absorbed by the third heat spreader 30.

The SOA 60 is a CoC-type light source that outputs light to the SiP element 40.

The shape of the third heat spreader 30 (the third surface 30S1 and the opposite surface 30S2) in plan view is not particularly limited, but may be, for example, a shape in which a notch is formed in a part thereof. In this case, the BOA 50 may be attached to the second heat spreader 20 at the portion of the opposite surface 20S2 of the second surface 20S1 that is not in contact with the third surface 30S1, and corresponds to the notch as described above.

In addition, the first heat spreader 10, the second heat spreader 20, and the third heat spreader 30 may be formed by metal plates different from each other. Alternatively, the first heat spreader 10, the second heat spreader 20, and the third heat spreader 30 may be formed by a single metal plate.

As described above, according to the fifth example embodiment, the third heat spreader 30 and the SOA 60 are added to the optical module 1. The third heat spreader 30 has the third surface 30S1 having a smaller area than the opposite surface 20S2 of the second surface 20S1, and is attached to the second heat spreader 20 after the third surface 30S1 and the opposite surface 20S2 of the second surface 20S1 are in contact with each other. The BOA 50 is attached to the second heat spreader 20 at a portion of the opposite surface 20S2 of the second surface 20S1 that is not in contact with the third surface 30S1. Further, the SOA 60 is attached to the third heat spreader 30 on the opposite surface 30S2 of the third surface 30S1. Thus, when the thickness of the BOA 50 is larger than the thickness of the SOA 60, the difference between the thicknesses of the two can be absorbed by the third heat spreader 30.

Other effects are the same as those of the first example embodiment described above.

In the fifth example embodiment, the thickness of the BOA 50 is assumed to be larger than the thickness of the SOA 60, but the thickness of the SOA 60 may be larger than the thickness of the BOA 50. In this case, the SOA 60 may be attached to the second heat spreader 20 at a portion of the opposite surface 20S2 of the second surface 20S1 that is not in contact with the third surface 30S1, and the BOA 50 may be attached to the third heat spreader 30 at the opposite surface 30S2 of the third surface 30S1.

### Sixth Example Embodiment

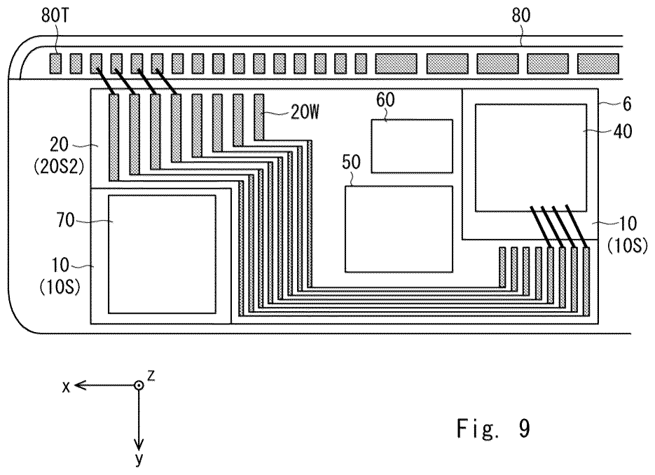

A configuration example of an optical module 6 will be described with reference to FIG. 9. FIG. 9 is a plan view illustrating a configuration example of the optical module 6.

As illustrated in FIG. 9, the basic configuration of the optical module 6 is the same as that of the optical module 4 described above.

The optical module 6 is mounted on a package 80.

In the second heat spreader 20, wiring 20W for connecting a terminal 80T of the package 80 and a terminal (not illustrated) of the SiP element 40 is provided on the opposite surface 20S2 of the second surface 20S1. Specifically, in the example of FIG. 9, the second heat spreader 20 (the second surface 20S1 and the opposite surface 20S2) has a Z shape in which notches are formed at two diagonal corners of a rectangle in plan view. In the opposite surface 20S2 of the Z shape, the wiring 20W is formed at a portion other than the attachment positions of the BOA 50 and the SOA 60.

As described above, according to the sixth example embodiment, the optical module 6 has the same configuration as the optical module 4 described above, and is mounted on the package 80. In the second heat spreader 20, the wiring 20W for connecting the terminal 80T of the package 80 and the terminal of the SiP element 40 is provided on the opposite surface 20S2 of the second surface 20S1. Thus, the terminal 80T of the package 80 and the terminal of the SiP element 40 can be connected to each other.

Other effects are the same as those of the fourth example embodiment described above.

Although the present disclosure has been described with reference to the example embodiments, the present disclosure is not limited to the above-described example embodiments. Various changes that can be understood by a person skilled in the art within the scope of the present disclosure can be made to the configuration and details of the present disclosure. Each example embodiment can be combined with other example embodiments as appropriate.

Also, the drawings are merely illustrative of one or more example embodiments. Each drawing may be associated with one or more other example embodiments, rather than only one particular example embodiment. As those skilled in the art will appreciate, various features described with reference to any one of the figures may be combined with features illustrated in one or more other figures, e.g., to create example embodiments not explicitly illustrated or described. All of the features illustrated in any one of the figures are not necessarily essential for describing the example embodiments, and some features may be omitted.

In addition, some or all of the above-described example embodiments may be described as the following supplementary notes, but are not limited thereto.

### (Supplementary Note 1)

An optical module including: a first heat spreader configured to have a first surface; a second heat spreader configured to have a second surface with a smaller area than the first surface and be attached to the first heat spreader after the second surface and the first surface are in contact with each other; an optical processing circuit configured to be attached to the first heat spreader at a portion of the first surface that is not in contact with the second surface, and process and output light; and an optical amplifier configured to be attached to the second heat spreader at an opposite surface of the second surface, and amplify and output the light being output from the optical processing circuit.

### (Supplementary Note 2)

The optical module according to Supplementary note 1, in which
the optical processing circuit includes an optical output port for outputting the light,
the optical amplifier includes an optical input port to which the light being output from the optical output port is input, and
a thickness of the second heat spreader is a difference between a first length from a bottom surface of the optical processing circuit to the optical output port and a second length from a bottom surface of the optical amplifier to the optical input port.

### (Supplementary Note 3)

The optical module according to Supplementary note 1, further including a light source configured to be attached to the second heat spreader on an opposite surface of the second surface and output light to the optical processing circuit.

### (Supplementary Note 4)

The optical module according to Supplementary note 3, further including an isolator configured to be attached to the first heat spreader at a portion of the first surface that is not in contact with the second surface, and transmit light being output from the optical amplifier in an output direction of the light.

### (Supplementary Note 5)

The optical module according to Supplementary note 4, in which the second heat spreader has a Z shape in which notches are formed at two diagonal corners of a square or a rectangle in plan view, the isolator is attached to the first heat spreader at a portion of the first surface that is not in contact with the second surface and is associated with one of the notches, and the optical processing circuit is attached to the first heat spreader at a portion of the first surface that is not in contact with the second surface and is associated with another of the notches.

### (Supplementary Note 6)

The optical module according to Supplementary note 5, in which the optical module is mounted on a package, and the second heat spreader is provided with wiring for connecting a terminal of the package and a terminal of the optical processing circuit on an opposite surface of the second surface.

### (Supplementary Note 7)

The optical module according to Supplementary note 1, in which the first heat spreader and the second heat spreader are formed of metal plates different from one another.

### (Supplementary Note 8)

The optical module according to Supplementary note 1, in which the first heat spreader and the second heat spreader are formed of a single metal plate.

### (Supplementary Note 9)

The optical module according to Supplementary note 1, further including: a third heat spreader configured to have a third surface having a smaller area than an opposite surface of the second surface and be attached to the second heat spreader after the third surface and the opposite surface of the second surface are in contact with each other; and a light source configured to be attached to the third heat spreader on an opposite surface of the third surface and output light to the optical processing circuit, in which the optical amplifier is attached to the second heat spreader at a portion of the opposite surface of the second surface that is not in contact with the third surface.

### (Supplementary Note 10)

The optical module according to Supplementary note 9, in which the first heat spreader, the second heat spreader, and the third heat spreader are formed of metal plates different from one another.

### (Supplementary Note 11)

The optical module according to Supplementary note 9, in which the first heat spreader, the second heat spreader, and the third heat spreader are formed of a single metal plate.

What is claimed is:

1. An optical module comprising:
a first heat spreader configured to have a first surface;
a second heat spreader configured to have a second surface having a smaller area than the first surface and be attached to the first heat spreader after the second surface and the first surface are in contact with each other;
an optical processing circuit configured to be attached to the first heat spreader at a portion of the first surface that is not in contact with the second surface, and process and output light; and
an optical amplifier configured to be attached to the second heat spreader on an opposite surface of the second surface, and amplify and output the light being output from the optical processing circuit.

2. The optical module according to claim 1, wherein
the optical processing circuit includes an optical output port for outputting the light,
the optical amplifier includes an optical input port to which the light being output from the optical output port is input, and
a thickness of the second heat spreader is a difference between a first length from a bottom surface of the optical processing circuit to the optical output port and a second length from a bottom surface of the optical amplifier to the optical input port.

3. The optical module according to claim 1, further comprising a light source configured to be attached to the second heat spreader on an opposite surface of the second surface, and output light to the optical processing circuit.

4. The optical module according to claim 3, further comprising an isolator configured to be attached to the first heat spreader at a portion of the first surface that is not in contact with the second surface, and transmit light being output from the optical amplifier in an output direction of the light.

5. The optical module according to claim 4, wherein
the second heat spreader has a Z shape in which notches are formed at two diagonal corners of a square or a rectangle in plan view,
the isolator is attached to the first heat spreader at a portion of the first surface that is not in contact with the second surface and is associated with one of the notches, and
the optical processing circuit is attached to the first heat spreader at a portion of the first surface that is not in contact with the second surface and is associated with another of the notches.

6. The optical module according to claim 5, wherein
the optical module is mounted on a package, and
the second heat spreader is provided with wiring for connecting a terminal of the package and a terminal of the optical processing circuit on an opposite surface of the second surface.

7. The optical module according to claim 1, wherein the first heat spreader and the second heat spreader are formed of metal plates different from one another.

8. The optical module according to claim 1, wherein the first heat spreader and the second heat spreader are formed of a single metal plate.

9. The optical module according to claim 1, further comprising:
a third heat spreader configured to have a third surface having a smaller area than an opposite surface of the second surface and be attached to the second heat spreader after the third surface and the opposite surface of the second surface are in contact with each other; and
a light source configured to be attached to the third heat spreader on an opposite surface of the third surface and output light to the optical processing circuit, wherein
the optical amplifier is attached to the second heat spreader at a portion of the opposite surface of the second surface that is not in contact with the third surface.

10. The optical module of claim 9, wherein the first heat spreader, the second heat spreader, and the third heat spreader are formed of metal plates different from one another.

11. The optical module of claim 9, wherein the first heat spreader, the second heat spreader, and the third heat spreader are formed of a single metal plate.
